(19) United States
(12) Patent Application Publication
(10) Pub. No.: US 2015/0214442 A1
(43) Pub. Date: Jul. 30, 2015

(54) LIGHT EMITTING DIODE PACKAGE STRUCTURE AND METHOD THEREOF

(71) Applicant: Lextar Electronics Corporation, Hsinchu (TW)

(72) Inventors: Ching-Chi Chiang, Hsinchu City (TW); Yung-Yi Liao, Changhua County (TW); Wei-Yi Hsu, Tainan City (TW); Cheng-Hung Yang, Miaoli City, Miaoli County (TW)

(73) Assignee: Lextar Electronics Corporation, Hsinchu (TW)

(21) Appl. No.: 14/294,214

(22) Filed: Jun. 3, 2014

(30) Foreign Application Priority Data
Jan. 28, 2014 (TW) 103103072

(51) Int. Cl. H01L 33/50; H01L 33/00; H01L 33/56; H01L 27/15

(52) U.S. Cl. CPC H01L 33/502; H01L 27/15; H01L 33/0095; H01L 33/56; H01L 2933/0033; H01L 2933/0041; H01L 2933/005

(57) ABSTRACT

A light emitting diode (LED) package structure is provided. The LED package structure comprises a substrate, at least one LED chip, an encapsulating compound and a curing material. The substrate has a first surface and a second surface opposite to the first surface. The LED chip is disposed on the first surface. The encapsulating compound covers the LED chip. The encapsulating compound has a plurality of particulate phosphors therein. The phosphors are centralized near a side of the encapsulating compound away from the substrate. The curing material is adhered to the side of the encapsulating compound away from the substrate.

This application claims the benefit of Taiwan application Serial No. 103103072, filed Jan. 28, 2014, the subject matter of which is incorporated herein by reference.

### BACKGROUND OF THE INVENTION

1. Field of the Invention

The invention relates in general to a semiconductor device, and more particularly to a light emitting diode (LED) package structure and a method thereof.

2. Description of the Related Art

In the technology field of light emitting diode (LED), fluorescent powders can be used to emit light for white lighting. For example, a white light can be generated by exciting yellow fluorescent powders with a light from a high intensity blue LED chip, exciting red and green fluorescent powders with a light from a high intensity blue LED chip or exciting red, green and blue fluorescent powders with a light from a UV-light LED chip. However, when a fluorescent powder is exposed in an environment with high temperature and high humidity, the reliability of the fluorescent powder will be affected, and problems such as color cast (color shift) and reduced lifespan will occur and further affect luminous efficiency of the white light LED chip.

In general, fluorescent powder is particulate phosphors either suspended inside the encapsulating compound or depositing on the peripheral surface of the LED chip. However, the encapsulating compound containing phosphors used in current dispensing technology cannot produce satisfactory dispersing effect, and may easily cause a non-uniform distribution of phosphors. Furthermore, if the phosphors are centralized near the peripheral surface of the LED chip by using deposition method, the phosphors will be too close to the peripheral area of the LED chip, and both the thermal stability and chemical stability of the phosphors will be affected. Thus, how to improve the thermal stability and chemical stability of phosphors has become a prominent task for the industries.

### SUMMARY OF THE INVENTION

The invention is directed to a light emitting diode (LED) package structure and a method thereof capable of disposing phosphors away from the peripheral area of the LED chip to increase the thermal stability and chemical stability of the phosphors.

According to one embodiment of the present invention, a light emitting diode (LED) package structure is provided. The LED package structure comprises a substrate, at least one LED chip, an encapsulating compound and a curing material. The substrate has a first surface and a second surface opposite to the first surface. The LED chip is disposed on the first surface, the encapsulating compound covers the LED chip, and the encapsulating compound has a plurality of particulate phosphors centralized near a side of the encapsulating compound away from the substrate. The curing material is adhered to the side of the encapsulating compound away from the substrate.

According to another embodiment of the present invention, an LED packaging method is provided. The method comprises following steps. A substrate having at least one LED chip and a package body is provided, wherein the package body surrounds the LED chip and has an opening exposing the LED chip. An encapsulating compound is dispensed into the opening of the package body, wherein the encapsulating compound covers the LED chip and has a plurality of particulate phosphors therein. A curing material is sprayed on a side of the encapsulating compound away from the substrate and is cured to seal the encapsulating compound in the opening of the package body to form a first LED package unit. The first LED package unit is inverted, such that the phosphors inside the encapsulating compound are centralized near the side of the encapsulating compound away from the substrate due to gravity. The encapsulating compound is heated and cured to form a second LED package unit.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1˜6 are respective steps of an LED packaging method according to an embodiment of the invention.

FIG. 7 is a schematic diagram of an LED package structure according to an embodiment of the invention.

### DETAILED DESCRIPTION OF THE INVENTION

An LED packaging method is disclosed in an example of the present embodiment. Firstly, particulate phosphors are interposed into a non-cured encapsulating compound such that the phosphors are suspended inside the encapsulating compound. Next, a curing material is sprayed on the encapsulating compound. That is, a curing material is sprayed on a side of the encapsulating compound away from the substrate to seal the non-cured encapsulating compound in the opening of the package body to form an LED package unit. Then, the LED package unit is inverted and held for a period of time. That is, the side of the encapsulating compound away from the substrate faces downwards, such that the phosphors, which were originally dispersed inside the encapsulating compound, deposit downward and are centralized near a side of the encapsulating compound away from the substrate.

In an example of the present embodiment, after the curing material was cured, a centrifugal treatment can be performed to accelerate the deposition of the phosphors inside the encapsulating compound such that the phosphors are centralized near a side of the encapsulating compound away from the substrate.

In an example of the present embodiment, the curing material, for example, a photo-curing material or a thermal curing material, can be realized by a coagulant or an adhesive. The curing material can seal the encapsulating compound in the opening of the package body by way of low-temperature thermal curing or UV-light curing within a shorter period of time.

A number of embodiments are disclosed below for elaborating the invention. However, the embodiments of the invention are for detailed descriptions only, not for limiting the scope of protection of the invention.

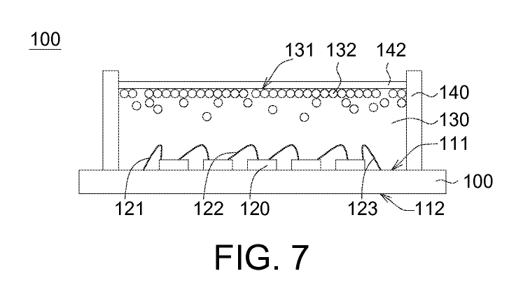

Referring to FIG. 7, a schematic diagram of an LED package structure 100 according to an embodiment of the invention is shown. In the present embodiment, a plurality of LED chips 120 are taken for example. The LED package structure 100 comprises a substrate 110, a plurality of LED chips 120, an encapsulating compound 130, a package body 140 and a curing material 142. Every two LED chips 120 are connected by a conducting wire 122 to form a series connection, and the outmost two LED chips 120 are electrically to the substrate 110 by conducting wires 121 and 123 respectively. However, the invention is not limited to the said disposition. For example, one single LED chip 120 is disposed on the substrate 110 and electrically connected to the electrodes of the substrate 110 by two conducting wires. Or, the LED chip 120 disposed on the substrate 110 can be a flip-chip LED or a vertical-type LED.

The substrate 110 has a first surface 111 and a second surface 112 opposite to the first surface 111. Each LED chip 120 is disposed on the first surface 111 of the substrate 110. The encapsulating compound 130 covers the LED chips 120, and is sealed within an area enclosed by the substrate 110, the package body 140 and the curing material 142.

The substrate 110 is, for example, a circuit board, a ceramic substrate or a metal core printed circuit board (MCPCB). In addition, the encapsulating compound 130 has a plurality of particulate phosphors 132 centralized near a side 131 of the encapsulating compound 130 away from the substrate 110, that is, the side 131 covered by the curing material 142.

The curing material 142 is adhered to the side 131 of the encapsulating compound 130 away from the substrate 110. In an embodiment, the curing material 142, being a thermal curing material, can be realized by a translucent material such as epoxy or silica gel, or an adhesive material such as a coagulant or an adhesive. The curing material 142 can be directly sprayed on a surface of the encapsulating compound 130, and can be heated at a low temperature (such as between 50˜70° C.) for a predetermined period of time, such that the curing material 142 can be heated and cured to seal the encapsulating compound 130 within an area enclosed by the substrate 110, the package body 140 and the curing material 142. In another embodiment, the curing material 142, being a photo-curing material, can be realized by a UV light curable resin, and can be directly sprayed on a surface of the encapsulating compound 130 and radiated by a UV light for a predetermined period of time to cure the curing material 142.

To increase the light extraction efficiency, the curing material 142 can be selected from a material with low refractive index so that the curing material 142 has a refractive index less than that of the encapsulating compound 130. In an embodiment, the encapsulating compound 130 has a refractive index between 1.4˜1.54, and the curing material 142 has a refractive index less than 1.54 or 1.4 such that the difference between the refractive indexes of the curing material 142 and the air will not be too large to generate total reflection.

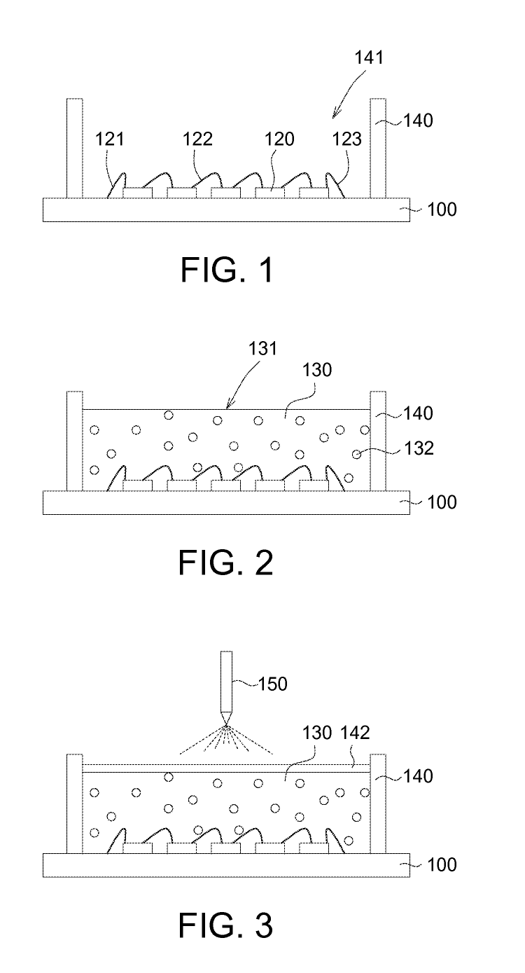

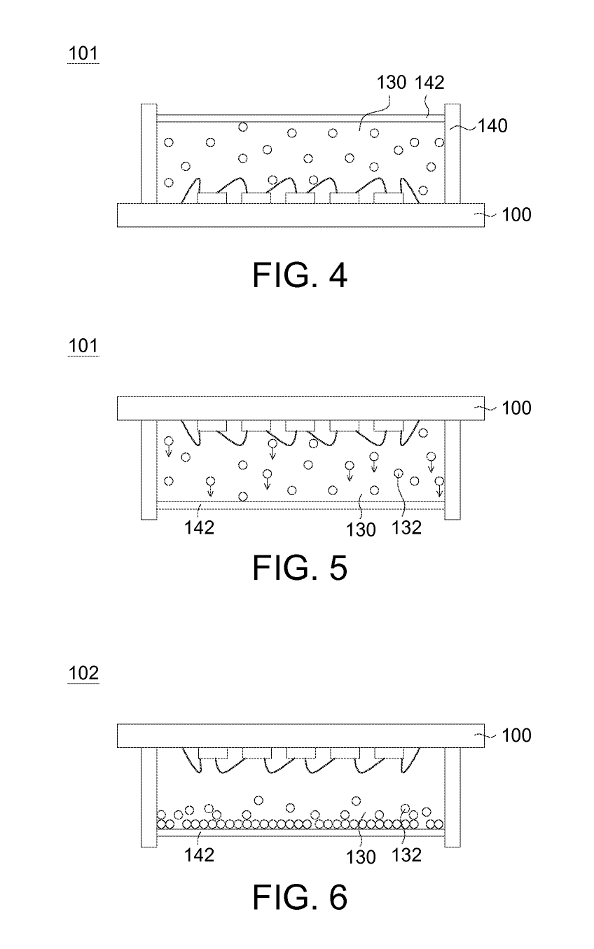

An LED packaging method used in an embodiment is disclosed below with FIGS. 1˜6 illustrating respective steps of the LED packaging method.

Please refer to FIG. 1. A substrate 110 is provided. A plurality of LED chips 120 are disposed on and electrically connected to the substrate 110. Besides, the package body 140 surrounds the LED chips 120, and has an opening 141 exposing the LED chips 120. In an embodiment, if the package body 140 is a mold, after LED packaging is completed, the package body 140 can be de-molded and removed from the substrate 110.

Please refer to FIG. 2. An encapsulating compound 130 is dispensed into the opening 141 of the package body 140. The encapsulating compound 130 covers the LED chips 120, and has particulate phosphors 132. Meanwhile, the particulate phosphors 132 are randomly distributed inside the encapsulating compound 130, and the encapsulating compound 130 is still non-cured.

Please refer to FIGS. 3˜4. A curing material 142 is sprayed on a side 131 of the encapsulating compound 30 away from the substrate 110 by a spray gun 150. Then, the curing material 142 sprayed on the encapsulating compound 130 is cured by a light source or a heat source to seal the encapsulating compound 130 in the opening 141 of the package body 140. As indicated in FIG. 4, the curing material 142, having been cured by light or heat, forms a first LED package unit 101 with the substrate 110 and the package body 140. Meanwhile, the particulate phosphors 132 inside the encapsulating compound 130 still do not deposit.

Please refer to FIG. 5. The first LED package unit 101 is inverted, such that the side 131 of the encapsulating compound 130 away from the substrate 110 faces downward. After a period of time, the particulate phosphors 132 inside the encapsulating compound 130 deposit due to gravity and are centralized near the side 131 of the encapsulating compound 130 away from the substrate 110, that is, the side 131 covered by the curing material 142. Since the curing material 142 is already cured, the non-cured inverted encapsulating compound 130 will not overflow from the package body 140.

As indicated in FIG. 5, the natural deposition speed of the particulate phosphors 132 is affected by the viscosity of the encapsulating compound 130 and the particle size of the particulate phosphors 132. To accelerate the deposition speed, a centrifugal treatment can be performed on the particulate phosphors 132 after the curing material 142 is cured. For example, the first LED package unit 101 is placed in a centrifuge with the side 131 of the encapsulating compound 130 away from the substrate 110 facing outward. Then, the first LED package unit 101 is rotated at a high speed to accelerate the deposition of the particulate phosphors 132 inside the encapsulating compound 130 such that the phosphors are centralized near the side 131 of the encapsulating compound 130 away from the substrate 110.

Please refer to FIG. 6. After most particulate phosphors 132 inside the encapsulating compound 130 have deposited, the encapsulating compound 130 is cured by heat to form a second LED package unit 102. In an embodiment, the encapsulating compound 130 may comprise epoxy and coagulant, the curing temperature is about 135° C., and the curing time is about 10˜20 minutes. In comparison to the curing material 142 in FIG. 3, the curing material 142 has a lower curing temperature about 50˜70° C. which is much lower than that of the encapsulating compound 130, and has a shorter curing time, so that the manufacturing time can be reduced.

As indicated in FIG. 6, the remote type particulate phosphors 132 are far away from the LED chip 120 so that the thermal stability and chemical stability of the particulate phosphors 132 will not be affected. Besides, in comparison to the conventional fluorescent powder which is suspended inside the encapsulating compound, the remote type particulate phosphors 132 has a smaller consumption and the light output of the LED chips 120 is more uniformly distributed. Thus, color cast which is caused by non-uniform distribution of fluorescent powder will not occur.

According to the LED package structure and the method thereof disclosed in above embodiments, phosphors are away from the peripheral of the LED chip, so that the thermal stability and chemical stability of the phosphors are increased, the lifespan of the phosphors is prolonged, and the light output of the LED chips is more uniformly distributed.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED) package structure, comprising:
a substrate having a first surface and a second surface opposite to the first surface;
at least one LED chip disposed on the first surface;
an encapsulating compound covering the LED chip and having a plurality of particulate phosphors therein, wherein the phosphors are centralized near a side of the encapsulating compound away from the substrate; and
a curing material adhered to the side of the encapsulating compound away from the substrate.

2. The LED package structure according to claim 1, further comprising a package body which encapsulates and seals the encapsulating compound within an area enclosed by the substrate, the package body and the curing material.

3. The LED package structure according to claim 2, wherein the encapsulating compound is formed by a material comprising epoxy.

4. The LED package structure according to claim 3, wherein the curing material is a photo-curing material or a thermal curing material.

5. The LED package structure according to claim 4, wherein the curing material comprises epoxy, silica gel or UV light curable resin.

6. The LED package structure according to claim 5, wherein the curing material has a refractive index less than that of the encapsulating compound.

7. The LED package structure according to claim 6, wherein the curing material has a refractive index less than 1.54.

8. An LED packaging method, comprising:
providing a substrate having at least one LED chip and a package body, wherein the package body surrounds the LED chip and has an opening exposing the LED chip;
dispensing an encapsulating compound into the opening of the package body, wherein the encapsulating compound covers the LED chip and has a plurality of particulate phosphors therein;
spraying a curing material on a side of the encapsulating compound away from the substrate and curing the curing material to seal the encapsulating compound in the opening of the package body to form a first LED package unit;
inverting the first LED package unit, such that the phosphors inside the encapsulating compound are centralized near the side of the encapsulating compound away from the substrate due to gravity; and
heating and curing the encapsulating compound to form a second LED package unit.

9. The LED packaging method according to claim 8, wherein the curing material is cured by light or heat.

10. The LED packaging method according to claim 9, wherein the curing material has a curing temperature lower than that of the encapsulating compound.

11. The LED packaging method according to claim 10, wherein the curing material has a curing temperature between 50˜70° C.

12. The LED packaging method according to claim 8, wherein after the curing material is cured, the method further comprises performing a centrifugal treatment to accelerate the deposition of the phosphors inside the encapsulating compound such that the phosphors are centralized near the side of the encapsulating compound away from the substrate.
